(19) United States
(12) Patent Application Publication
(10) Pub. No.: US 2007/0004047 A1
(43) Pub. Date: Jan. 4, 2007

(54) Methods and apparatus for molecular data storage, retrieval and analysis

(76) Inventors: Jeremy S Lee, Saskatchewan (CA); Shawn Wettig, Saskatchewan (CA); Heinz-Bernhard Kraatz, Saskatchewan (CA)

Correspondence Address: Ralph A. Dowell of DOWELL & DOWELL P.C., 2111 Eisenhower Ave, Suite 406, Alexandria, VA, 22314, US

(21) Appl. No.: 10/511,841

(22) PCT Filed: Apr. 17, 2003
(86) PCT No.: PCT/CA03/00574

§ 371 Date: Jun. 27, 2005

Related U.S. Application Data
(60) Provisional application No. 60/373,644, filed on Apr. 19, 2002.

(51) Int. Cl. H01L 21/00

(52) U.S. Cl. 438/1

(57) ABSTRACT

In various aspects, the invention provides molecular systems for storing and retrieving information. In some embodiments, polymers capable of selectively binding metal ions, such as nucleic acids, are used to record information in the form of a particular molecular conformation. Electrochemical assay methods employing nanopores may be used to read and write information using such polymeric media. In some embodiments, information may be recorded in a nucleic acid polymer by magnetically modulating the translocation of the nucleic acid through a channel in a medium, while simultaneously modulating the electrostatic potential across the channel. In this way, the incorporation of a divalent metal ion in the nucleic acid duplex may be modulated to store information. In an alternative aspect, the invention provides analogous processes for detecting a base pair mismatch in a nucleic acid polymer.

### FIELD OF THE INVENTION

The invention is in the field of molecular-scale devices for analysing molecules, and methods of using such devices. More particularly, it relates to molecular information storage and information retrieval systems.

### BACKGROUND OF THE INVENTION

It has long been known that DNA is an efficient means for storing vast amounts of information in a very small space. DNA as it is stored inside somatic cells may be thought of as read-only memory (ROM), inasmuch as the information stored in these DNA molecules is generally not ‘written’. Biochemical methods for “writing” (assembling oligonucleotides) and reading (sequencing) DNA have thus far not been easily adapted to non-biological memory devices.

Alternative methods are known for using polymers for electronic molecular memories (see Heller and Tu, U.S. Pat. No. 6,067,246). For example, Hopfield et al. disclose a polymer based shift register memory which incorporates charge transfer groups. Others have proposed an electronic memory device in which DNA is used with electron conducting polymers (Robinson et al).

There are many applications for methods that may be used to read the biological information recorded by DNA. For example, methods for the detection of single nucleotide polymorphisms (SNP's) in nucleic acid sequences have many important applications, potentially including mutagenicity assessment of drugs and chemicals, measuring environmental levels of genotoxins, cancer cell detection and methods of screening for genetic diseases. SNPs may be detected as base-pair mismatches in a DNA duplex. Present methods for the detection of base-pair mismatches primarily involve biochemical sequencing techniques. An innovative method has been described for using a hemolysin nanopore to detect the blockade events caused by single DNA hairpin molecules to provide sequence information at a single nucleotide resolution (Vercoutere et al). Similar methods have been used that employ a DNA oligonucleotide tethered within the lumen of a hemolysin nanopore to detect differences in ionic current flow through the pore (Howorka et al.).

Nanopores have previously been used for the characterization of polymeric molecules. For example, U.S. Pat. Nos. 6,267,872; 6,015,714 and 5,795,782 (incorporated herein by reference) disclose methods and apparatus for the characterization of polymeric molecules such as nucleic acids using thin film supports containing ion-permeable nanometer-scale channels, frequently called nanopores. There have been numerous reports describing methods for the rapid characterization of polynucleotides passing through a lipid bilayer by measuring ionic current changes at nanopores (Kasianowicz et al.; Akeson et al.; Meller et al.; Howorka et al.; Vercoutere et al.; Howorka et al. Nat. Biotech.; all of which are incorporated herein by reference).

A new form of conductive nucleic acid, called M-DNA, has recently been described in which the imino protons of each base pair may be replaced by a metal ion such as Zn²⁺, Ni²⁺ or Co²⁺ (International Patent Publication WO 99/31115; Aich et al.; and Rakitin et al.; all of which are incorporated herein by reference).

### SUMMARY OF THE INVENTION

In one aspect, the invention provides processes for recording information in a polymer, such as a nucleic acid polymer. The invention also provides devices for storing information, such as a device comprising a metal-containing nucleic acid duplex housed in the lumin of a channel formed in a membrane. Processes for using such devices may involve providing a channel separating a hybridization medium and a dissociation medium. The channel may be dimensioned to allow lineal translocation of a nucleic acid duplex or a metal-containing nucleic acid duplex between the hybridization medium and the dissociation medium. A first strand of nucleic acid may be provided with a second strand of nucleic acid, the first and the second nucleic acid strands comprising a plurality of nitrogen-containing aromatic bases covalently linked by a backbone. The nitrogen-containing aromatic bases of the first nucleic acid strand may be capable of being joined by hydrogen bonding in the hybridization medium to the nitrogen-containing aromatic bases of the second nucleic acid strand, so that the nitrogen-containing aromatic bases on the first and the second nucleic acid strands form hydrogen-bonded base pairs in stacked arrangement in the nucleic acid duplex. The hydrogen-bonded base pairs may be capable of interchelating a divalent metal cation coordinated to a nitrogen atom in one of the aromatic nitrogen-containing aromatic bases to form the metal-containing nucleic acid duplex.

In some embodiments, information may be recorded in the nucleic acid polymer by modulating the translocation of the first and second strands of nucleic acid through the channel between the dissociation medium and the hybridization medium, while modulating the electrostatic potential across the channel. In this way, the incorporation of the divalent metal ion in the nucleic acid duplex may be modulated as the duplex forms in the hybridization medium. Information may be read from the nucleic acid polymer by detecting the presence or absence of the divalent metal cation in the nucleic acid duplex. The presence or absence of the divalent metal cation may for example be detected by measuring the electrical conductance across the channel as the nucleic acid duplex is translocated through the channel between the hybridization medium and the dissociation medium. The nucleic acid duplex may for example be coupled to a magnetic bead, and the translocation of the nucleic acid duplex through the channel may be mediated by modulating a magnetic field across the channel.

In alternative embodiments, the channel may be formed in a lipid membrane, for example using a pore forming protein. The hybridization medium and the dissociation medium may be electrically conductive aqueous solutions. The polymer may be a deoxyribonucleic acid, and the nitrogen-containing aromatic bases may be selected from the group consisting of adenine, thymine, guanine and cytosine. The process of any one of claims 1 through 8 wherein the divalent metal cation is selected from the group consisting of Zn²⁺, Co²⁺, and Ni²⁺. The divalent metal cations may be substituted for imine protons of the nitrogen-containing aromatic bases, and the nitrogen-containing aromatic bases are selected from the group consisting of thymine and guanosine. At least one of the aromatic nitrogen-containing aromatic bases may be thymine, having an N3 nitrogen atom, and the divalent metal cation may be coordinated by the N3 nitrogen atom. At least one of the aromatic nitrogen-containing aromatic bases may be guanine, having an N1 nitrogen atom, and the divalent metal cation may be coordinated by the N1 nitrogen atom.

In some embodiments, the invention utilises a polymer capable of selectively binding a metal ion when single strands of the polymer join to form a duplex. In some embodiments, adjacent media compartments may be provided separated by a non-conducting membrane, such that the polymer favours the formation of single strands on one side of the membrane and duplex formation is favoured on the other side of the membrane. The solution that favours the formation of single stranded polymers also contains metal ions in solution capable of diffusing through the solution. The membrane also defines a nanopore sufficient to accommodate the length-wise passage of the polymer through the nanopore one base-pair at a time. In the ‘write’ mode the polymer passes from the solution favouring single strand formation through the pore into the solution favouring duplex formation. As the polymer passes through the pore in the write mode a metal ion can be selectively incorporated at each base-pair position by applying an appropriate potential to the pore. An alternative potential may be applied to repel the metal ion, facilitating the formation of base pairs that lack a metal ion. In the ‘read’ mode the polymer passes from the solution favouring duplex formation through the pore into the solution favouring single strand formation. The nanopore in the read mode provides a means for detecting the presence or absence of a metal ion in the base pairs of the duplex as the polymer passes through the pore.

In an alternative aspect, the invention provides processes for detecting a base pair mismatch is a nucleic acid polymer. In such processes, a channel may be provided separating a first pool and a second pool of a medium. The channel may be dimensioned to allow sequential monomer-by-monomer lineal translocation of a polymer, such as a metal-containing nucleic acid duplex, between the first and second pools of the medium. Where the polymer is a metal-containing nucleic acid duplex, the nucleic acid duplex may comprise a first strand of nucleic acid and a second strand of nucleic acid, the first and the second nucleic acid strands comprising a plurality of nitrogen-containing aromatic bases covalently linked by a backbone. At least some of the nitrogen-containing aromatic bases of the first nucleic acid strand may match the nitrogen-containing aromatic bases of the second nucleic acid strand, and the matching base pairs may be joined by hydrogen bonding to the nitrogen-containing aromatic bases of the second nucleic acid strand. The matching nitrogen-containing aromatic bases on the first and the second nucleic acid strands may form hydrogen-bonded base pairs in stacked arrangement along the length of the nucleic acid duplex. The nucleic acid duplex may be subjected to a basic solution in the presence of a divalent metal cation, under conditions effective to form a metal-containing nucleic acid duplex. The matching hydrogen-bonded base pairs of the metal-containing nucleic acid duplex may comprise an interchelated divalent metal cation coordinated to a nitrogen atom in one of the aromatic nitrogen-containing aromatic bases, and wherein a mismatched base pair does not interchelate a divalent metal cation. The metal-containing nucleic acid duplex may be translocated through the channel from the first pool to the second pool, and the presence or absence of divalent metal cations in the base pairs of the nucleic acid duplex may be detected by measuring the electrical conductance across the channel as the metal-containing nucleic acid duplex is translocated through the channel between the first and second pools.

### BRIEF DESCRIPTION OF THE DRAWINGS

FIG. 1 is a schematic diagram showing the ‘write’ mode in which information is recorded in a nucleic acid molecule in one embodiment of the invention.

FIG. 2 is a schematic diagram showing the ‘read’ mode in which information is retrieved from a nucleic acid molecule in one embodiment of the invention.

FIG. 3 is a schematic diagram showing an implementation of the processes of the invention for base pair mismatch detection.

FIG. 4 is a pictorial representation of a putative modeled structure of M-DNA.

FIG. 5 is a pictorial depiction of a putative base pair scheme for M-DNA shown in FIG. 4, according to an alternate embodiment of the invention.

FIG. 6 is a pictorial depiction of a putative base pairing scheme for M-DNA shown in FIG. 4, according to an alternate embodiment of the invention.

FIG. 7 shows sequences and nomenclature used for the DNA analysed in the nanopore study described in the Example († calculated using MeltCalc software, see Schütz, E., Von Ahsen, N., BioTechniques 1999, 27, 1218-28).

FIG. 8 shows typical unfiltered DNA translocation events from the Example: (a) full blockage translocation event, (b) partial blockage event (c) partial blockage that results in a translocation event. The magnitude of the current blockage is labelled as iₚₑₐₖ and the duration of the blockage is labelled tau.

FIG. 9 gaussian fits to two distributions from the histograms of iₚₑₐₖ collected from (a) ss-DNA, Peak centre 1=−42(2) pA, fwhm=11(3) pA, Area=2(1); Peak centre 2=−81(1) pA, fwhm=10(1) pA, Area=13(1). (b) ds-DNA. Peak centre 1=−31(1) pA, fwhm=11(2) pA, Area=14(1); Peak centre 2=−73(3) pA, fwhm=7(4) pA, Area=1.4(0.8).

FIG. 10 current blockage duration histograms of (a) Guide:Match hybrid tau=1100(250) μs, (b) Guide:MM1 hybrid, tau=155(25) μs, (c) Guide:MM2 hybrid, tau=100(10) μs, (d) Guide:MM3 hybrid, tau=100(30) μs.

### DETAILED DESCRIPTION OF THE INVENTION

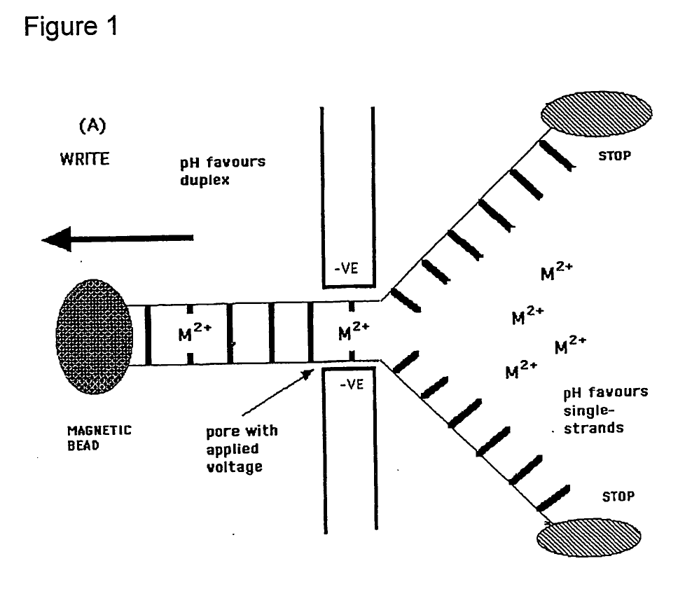

As shown in FIG. 1, in one aspect the invention provides systems for recording information in a polymer. The schematic diagram of FIG. 1 shows the ‘write’ mode of one embodiment, illustrating a nucleic acid strands being pulled (moving to the left in the Figure) into a duplex favoring hybridization solution. As illustrated, the translocation of the nucleic acid is mediated by a magnetic field acting on a magnetic bead attached to the nucleic acid. During sequential monomer-by-monomer lineal translocation of the nucleic acid polymer, the potential across the membrane may be modulated to control whether a metal ion is inserted into the helix. If a metal ion is permitted to enter the duplex, a metal-containing base pair is formed. If metal ions are excluded from the duplex, a non-metal-containing base pair is formed. Information is thereby stored in the duplex in the form of the presence or absence of metal ions in the duplex.

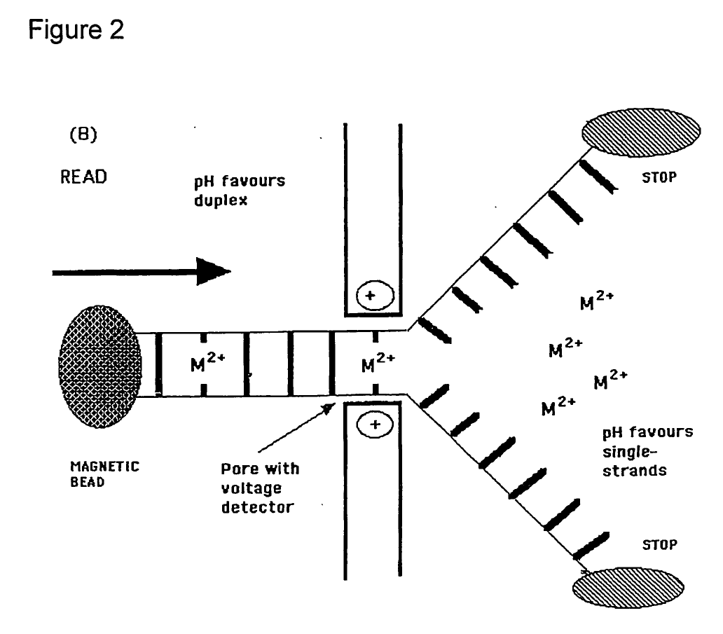

As shown in FIG. 2, in one aspect of the invention, information may be retrieved or read from polymers in a process that is in some respects a reversal of the foregoing process of writing information to the polymer. FIG. 1 is a schematic diagram showing the ‘read’ mode of one embodiment of the invention, in which the polymer, such as DNA, is pushed (translocated to the right in the Figure) into a single strand favoring ‘dissociation’ medium, such as an aqueous solution. As illustrated, the translocation of the polymer is mediated by a magnetic field acting on a magnetic bead attached to the polymer. As each base pair passes through the pore, a detector senses whether a metal ion is present or absent in the base pair. For example, U.S. Pat. 5,795,782 and 6,015,714 describe a variety of methods for characterization of polymers which are illustrative of alternative detection methods that may be used in the present invention.

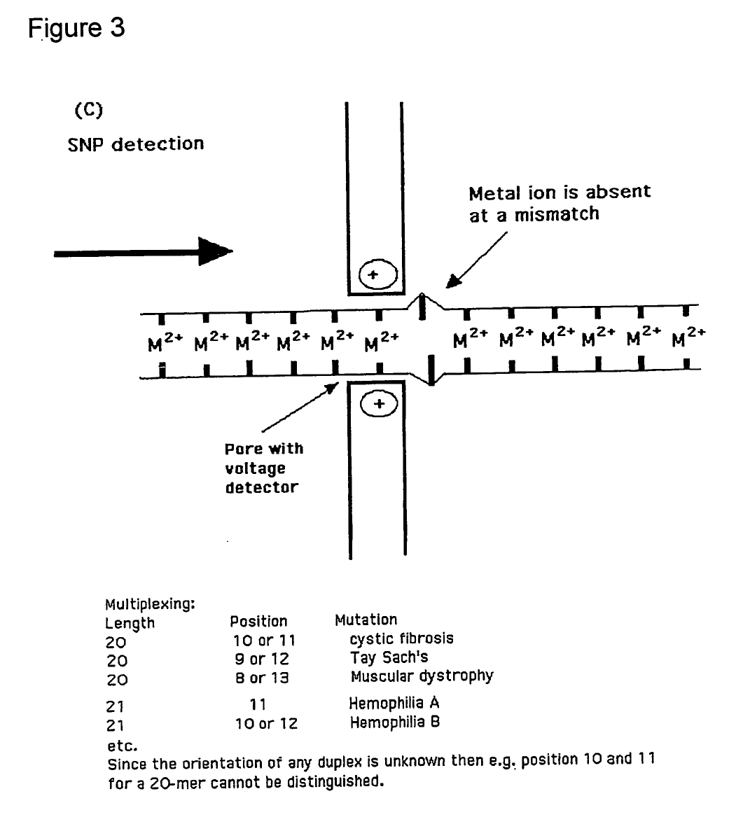

An alternative aspect of the invention is illustrated in FIG. 3, which is a schematic diagram showing a system for detecting base pair mismatches, such as are present in single nucleotide polymorphisms (SNP). In such embodiments, a DNA duplex, such as a duplex formed by hybridization of a probe and a target sequence, is passed through a pore or channel to detect the presence or absence of metal ions along the duplex. In such embodiments, conditions are provided so that as the duplex forms metal ions are incorporated at each matching base pair, and are not incorporated where a base-pair mismatch occurs. The detection of base pair mismatches is functionally similar to the ‘read’ mode shown in FIG. 2, with the presence or absence of a metal ion being detected as the duplex passes through the channel.

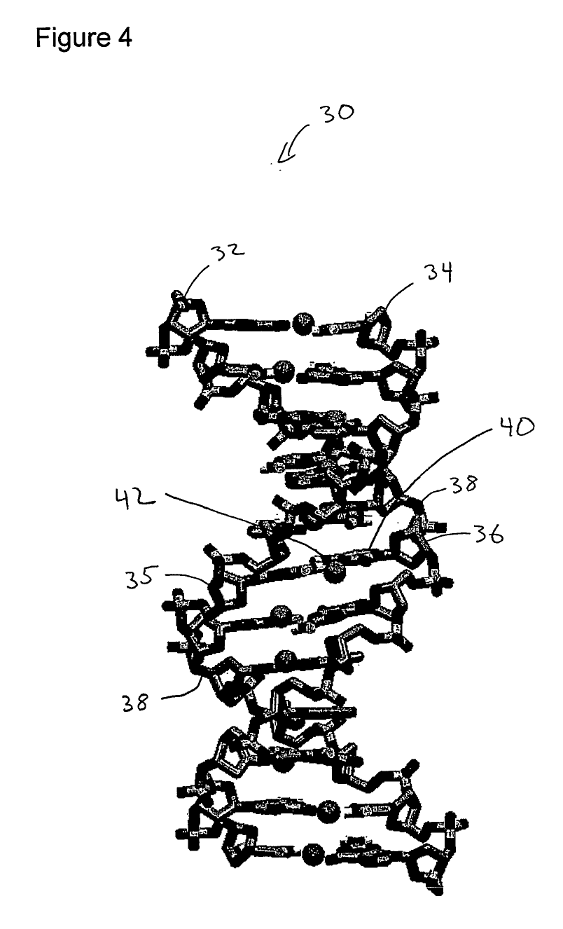

In some embodiments, the invention utilises nucleic acids that are related in structure to conductive metal-containing oligonucleotides as disclosed in International Patent Publication WO 99/31115, such as a metal-containing DNA duplex (“M-DNA”) shown at 30 in FIG. 4. As illustrated, M-DNA 30 comprises a first strand of nucleic acid 32 and a second strand of nucleic acid 34. The first 32 and the second 34 nucleic acid strands include a plurality of nitrogen-containing aromatic bases 35 and 36, respectively, covalently linked by a backbone 38. The nitrogen-containing aromatic bases 35 of the first nucleic acid strand 32 are joined by hydrogen bonding to the nitrogen-containing aromatic bases 36 of the second nucleic acid strand 34. The nitrogen-containing aromatic bases 35 and 36 on the first 32 and the second 34 nucleic acid strands, respectively, form hydrogen bonded base pairs 40 in stacked arrangement along the length of the metal-containing oligonucleotide duplex 30. The hydrogen-bonded base pairs 40 include an interchelated divalent metal cation 42 coordinated to a nitrogen atom in one of the nitrogen-containing aromatic bases 35 or 36. In the illustrated embodiment, the first and second nucleic acid strands 32 and 34 respectively are deoxyribonucleic acid and the nitrogen-containing aromatic bases 35 and 36 are selected from the group consisting of adenine, thymine, guanine and cytosine.

Alternatively, other backbone structures 38 may be effective to appropriately align the aromatic nitrogen-containing bases 35, 36 in a stacked arrangement capable of chelating metal ions 42 and conducting electrons. For example, phosphoramide, phosphorothioate, phosphorodithioate, O-methylphosphoroamidite or peptide nucleic acid linkages may be effective to form such a backbone. Similarly, other components of the backbone 38 may vary in accordance with the invention, encompassing the deoxyribose moieties, ribose moieties, or combinations thereof.

The nitrogen-containing aromatic bases 35 and 36 may be those that occur in native DNA and RNA, namely adenine, thymine, cytosine, guanine or uracil, or variants thereof such as 5-fluorouricil or 5-bromouracil. Alternative aromatic compounds may be utilized, such as aromatic compounds capable of interchelating a divalent metal ion coordinated to an atom in the aromatic compound, and capable of stacking, to produce a metal-containing oligonucleotide duplex. Alternative aromatic compounds may for example include: 4-acetylcytidine; 5-(carboxyhydroxymethyl) uridine; 2′-O-methylcytidine; 5-carboxymethylaminomethyl-2-thiouridine; 5-carboxymethylaminomethyluridine; dihydrouridine; 2′-O-methylpseudouridine; beta, D-galactosylqueuosine; 2′-O-methylguanosine; inosine; N6-isopentenyladenosine; 1-methyladenosine; 1-methylpseudouridine; 1-methylguanosine; 1-methylinosine; 2,2-dimethylguanosine; 2-methyladenosine; 2-methylguanosine; 3-methylcytidine; 5-methylcytidine; N6-methyladenosine; 7-methylguanosine; 5-methylaminomethyluridine; 5-methoxyaminomethyl-2-thiouridine; beta, D-mannosylqueuosine; 5-methoxycarbonylmethyl-2-thiouridine; 5-methoxycarbonylmethyluridine; 5-methoxyuridine; 2-methylthio-N6-isopentenyladenosine; N-((9-beta-D-ribofuranosyl-2-methylthiopurine-6-yl)carbamoyl)threonine; N-((9-beta-D-ribofuranosylpurine-6-yl) N-methycarbamoyl)threonine; uridine-5-oxyacetic acid-methylester; uridine-5-oxyacetic acid; pseudouridine; queuosine; 2-thiocytidine; 5-methyl-2-thiouridine; 2-thiouridine; 4-thiouridine; 5-methyluridine; N-((9-beta-D-ribofuranosylpurine-6-yl) -carbamoyl) threonine; 2′-O-methyl-5-methyluridine; and 2′-O-methyluridine; 3-(3-amino-3-carboxy-propyl) uridine; hypoxanthine, 6-methyladenine, 5-me pyrimidines, particularly 5-methylcytosine (also referred to as 5-methyl-2′deoxycytosine and often referred to in the art as 5-me-C), 5-hydroxymethylcytosine (HMC), glycosyl HMC and gentobiosyl HMC, as well as synthetic nucleobases. e.g., 2-aminoadenine, 2-thiouracil, 2-thiothymine, 5-bromouracil, 5-hydroxymethyluracil, 8-azaguanine, 7-deazaguanine, N⁶ (6-aminohexyl)adenine and 2,6-diaminopurine.

Oligonucleotides of the invention may include those containing modified backbones, for example, phosphorothioates, phosphotriesters, methyl phosphonates, short chain alkyl or cycloalkyl intersugar linkages or short chain heteroatomic or heterocyclic intersugar linkages. In some embodiments, the phosphodiester backbone of the oligonucleotide may be replaced with a polyamide backbone, the nucleobases being bound directly or indirectly to the aza nitrogen atoms of the polyamide backbone (Nielsen et al., Science, 1991, 254:1497). Oligonucleotides may also contain one or more substituted sugar moieties, such as moieties at the 2′ position: OH, SH, SCH₃, F, OCN, OCH₃ OCH₃, OCH₃ O(CH₂)ₙ, CH₃, O(CH₂)ₙ, NH₂ or O(CH₂)ₙ, CH₃ where n may for example be from 1 to about 10; C₁, to C₁₀ lower alkyl, alkoxyalkoxy, substituted lower alkyl, alkaryl or aralkyl; Cl; Br; CN; CF₃; OCF₃; O—, S—, or N-alkyl; O—, S—, or N-alkenyl; SOCH₃; SO₂ CH₃; ONO₂; NO₂; N₃; NH₂; heterocycloalkyl; heterocycloalkaryl; aminoalkylamino; polyalkylamino; substituted silyl; an RNA cleaving group; a reporter group; an intercalator; and other substituents having similar properties. Similar modifications may also be made at other positions on the oligonucleotide, particularly the 3′ position of the sugar on the 3′ terminal nucleotide and the 5′ position of 5′ terminal nucleotide. Oligonucleotides may also have sugar mimetics such as cyclobutyls in place of the pentofuranosyl group. Oligonucleotides may also include, additionally or alternatively, nucleobase (often referred to in the art simply as “base”) modifications or substitutions.

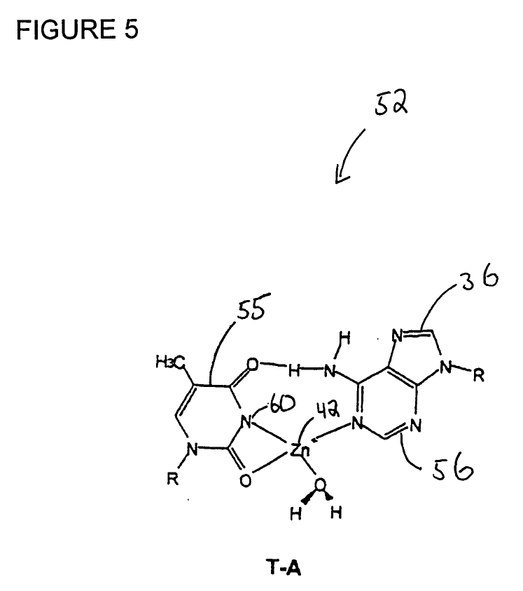

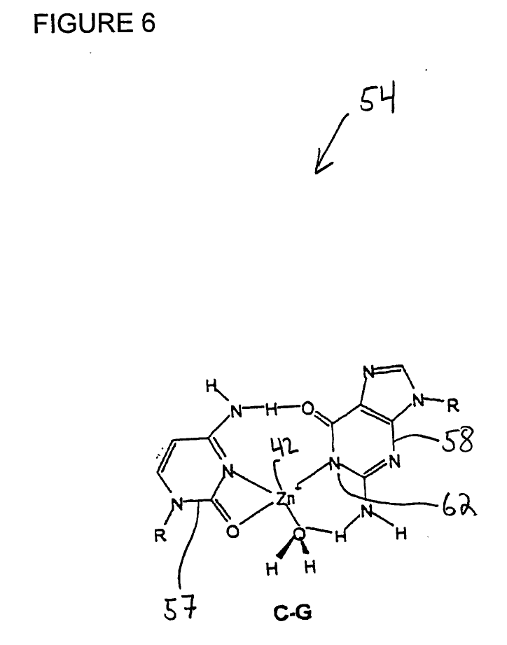

Referring to FIGS. 5 and 6, a pictorial depiction of base-pairing schemes for some embodiments of M-DNA is shown generally at 52 and 54. In some embodiments, as for example illustrated in FIG. 4, the estimated spacing between the divalent metal ions 42 may be about 3, 4 or 5 Å (Angstroms). A first embodiment shows a thymine-adenine base pair 52 in FIG. 5 and a second embodiment shows a cytosine-guanine base pair 54 in FIG. 6. In both of these embodiments 52 and 54, the divalent metal cation is zinc 42. Alternatively, the divalent metal cation 42 may be selected from the group consisting of zinc, cobalt or nickel. Alternative divalent metal ions may be utilized depending upon the ability of the ions to participate with the other substituents of the molecules of the invention in the formation of a metal-containing oligonucleotide duplex.

Referring to FIG. 5, in the thymine-adenine base pair 52, one aromatic nitrogen-containing aromatic base is thymine 55 which possesses an N3 nitrogen atom 60. The divalent metal cation zinc 42 is coordinated by the N3 nitrogen atom 60 of thymine 55, where the divalent metal cation zinc is substituted for an imine proton of the nitrogen-containing aromatic base. In an alternate embodiment shown in FIG. 6, in the cytosine-guanine base pair 54, the guanine 58 nitrogen-containing aromatic base has an N1 nitrogen atom 62 and the divalent metal cation zinc 42 is coordinated by the N1 nitrogen atom. Alternatively, the divalent metal cation 42 may be complexed between aromatic moieties in alternative conformations. In some embodiments, as illustrated, the imino protons of each base pair may be replaced by a metal ion.

In some embodiments, M-DNA 30 may be formed from B-DNA by the addition of metal ions, such as 0.1 mM Zn²⁺ or 0.1 mM NiCl₂ at an approximate pH, such as a pH of 9.0. There may be a concomitant release of protons, so that a base such as KOH may be added to maintain the pH at a desired level, such as at 8. The conditions necessary to form M-DNA 30 will vary depending on the metal ion 42 or ions used and the nature of the nucleic acid 32 and 34. Routine assays may be carried out to determine appropriate conditions for metal-containing duplex formation, for example by varying parameters such as pH, nucleic acid concentration, metal ion concentration, and the ratio of the metal ion concentration to the nucleic acid concentration. In some embodiments, a pH equal to or greater than 7, 7.5, 8, 8.5 or 9 may be required, and a suitable nucleic acid to metal ion ratio may be from about 1:1.5 to about 1:2.0.

In alternative embodiments, metal cations for incorporation into a metal-containing duplex of the invention may be selected from the group consisting of the cations of Li, Be, Na, Mg, Al, K, Ca, Sc, Ti, V, Cr, Mn, Fe, Co, Ni, Cu, Zn, Ga, Ge, As, Rb, Sr, Y, Zr, Nb, Mo, Tc, Ru, Rh, Pd, Ag, Cd, In, Sn, Sb, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, U, Np and Pu. For example, in some embodiments varying amounts of metal cations may be incorporated into a duplex, such as Zn²⁺, Ni²⁺, Co²⁺, Cd²⁺, Hg²⁺, Pt²⁺ and Ag¹⁺, where metal ions such as Cd²⁺, Hg²⁺, Pt²⁺ and Ag¹⁺ may constitute only a portion of the metal ions in the duplex, in effect ‘doping’ the duplex. The formation of a metal-containing duplex using alternative cations under alternative conditions may be monitored, for example, using an ethidium bromide fluorescence assay as described in International Patent Publication WO 99/31115. In some embodiments, conductive M-DNA may be coupled to electron donors or electron acceptors, which may for example facilitate detection of the formation of an M-DNA duplex. The electron donor may be a molecule capable of donating an electron to duplex, and the electron acceptor may be a molecule capable of accepting an electron from the duplex.

A variety of methods have been described for the formation of channels or nanopores with characteristics appropriate for use in alternative embodiments of the present invention. In some embodiments, a biological pore molecule may be used to form a channel through which to record the process of metal-containing polymer translocation. Channels may for example be isolated on a membrane patch or inserted into a synthetic lipid bilayer. For example, U.S. Pat. Nos. 5,795,782 and 6,015,714, disclose a use of the maltoporin (LamB) pore wherein DNA is passed through the maltoporin pore, or over its opening, and resulting conductance changes can be measured. Alternative embodiments of the invention may utilize channel proteins which have pore sizes of between 3 and 10nm. For example, U.S. Pat. Nos. 5,795,782 and 6,015,714 describe processes utilzing pores through which a polymer can be drawn having dimensions of approximately 0.5-2.0 nm for single stranded DNA; 1.0-3.0 nm for double stranded DNA; and 1.0-4.0 nm for polypeptides. U.S. Pat. Nos. 5,795,782 and 6,015,714 also describe examples of bacterial pore-forming proteins which may be used in alternative embodiments of the invention, such as Gramicidin (e.g., Gramicidin A from Bacillus brevis; available from Fluka, Ronkonkoma, N.Y.); LamB (maltoporin), OmpF, OmpC, or PhoE from Escherichia coli, Shigella, and other Enterobacteriaceae, alpha-hemolysin (from S. aureus), Tsx, the F-pilus, lambda exonuclease, and mitochondrial porin (VDAC).

It may be preferable in some embodiments to use biological pores that do not inactivate quickly, for example having inactivation times of more than about 500 msec. Inactivation times for pores may be natural characteristics of a selected pore, or may for example be adapted by modification of the pore to alter domains responsible for inactivation. Methods to alter inactivation characteristics of voltage gated channels are known in the art (see e.g., Patton, et al., Proc. Natl. Acad. Sci. USA, 89: 10905-09 (1992); West, et al., Proc. Natl. Acad. Sci. USA, 89: 10910-14 (1992); Auld, et al., Proc. Natl. Acad. Sci. USA, 87: 323-27 (1990); Lopez, et al., Neuron, 7: 327-36 (1991); Hoshi, et al., Neuron, 7: 547-56 (1991); Hoshi, et al., Science, 250: 533-38 (1990), all hereby incorporated by reference). Alternative embodiments may also use pores modified to have polymerase attachment sites (such as pores produced as recombinant fusion proteins). U.S. Pat. Nos. 5,795,782 and 6,015,714 describe, for example, methods in which a DNA polymerase molecule is fused to a pore molecule allowing the polymerase to move DNA over the pore's opening while recording the conductance across the pore.

To determine current modulation attributable to individual base pairs, one may use channels containing a limiting aperture that is much shorter than the full length of the overall channel (Weiss et al.). For example, one can modify alpha-hemolysin by standard molecular biological techniques such that portions of the pore leading to and away from the constriction are widened. Similarly, alternative biological pores could be modified using standard molecular biological techniques to modify the pore or channel to suit a specific purpose (Tapper and George, J Biol Chem 2001 Oct. 12;276(41):38249-54; Gu et al. Science 2001 291(5504):636-40; Chapman et al. J Physiol 530(1):21-33; Braha et al. Nat Biotechnol. 2000 18(9): 1005-7).

In alternative embodiments, non-biological channels or pores may also be provided. For example, a pore may be made in thin layers of conducting polymers using x-ray lithography or UV femtosecond lasers. Alternatively, a pore could be sculpted using ion-beams (as described by Li et al. (Nature 2001 412(6843):166-169). Li et al. describe a method of low energy ion-beam sculpting to produce nanopores in thin insulating solid state membranes (Si3N4 membrane). Additionally, mesomorphous materials such as clays, zeolites and carbon nanotubes may be used to create a pore or channel. In some embodiments, it may be possible to prepare and manipulate nanotubes as channels with a variety of diameters in the range of 3-10 nm (30-100 angstroms). U.S. Pat. Nos. 5,795,782 and 6,015,714 describe how appropriately sized physical or chemical pores or channels could be induced in a water-impermeable barrier (solid or membranous) up to a diameter of about 9 nm. Alternative methods and materials known in the art for channel forming may be used, including track etching and the use of porous membrane templates(e.g., methods utilizing a scanning-tunneling microscope or atomic force microscope). U.S. Pat. Nos. 5,795,782 and 6,015,714 also describe how chemical channels or pores can be formed in a lipid bilayer using chemicals (or peptides) such as Nystatin, as is well known in the art of whole-cell patch clamping (“perforated patch” technique); and peptide channels such as Alamethicin.

In some embodiments, the methods of the invention involve measurements of ionic current modulation as the monomers (such as nucleotides) of a linear polymer (such as a nucleic acid molecule) pass through or across a channel or nanopore in a membrane. During polymer passage through or across the channel, ionic currents are modulated in a manner that reflects the properties of the polymer and the monomers. Accordingly, in some embodiments of the invention, to establish an ionic current, or to modulate the incorporation of metal ions in a polymer, a voltage gradient may be established across a membrane containing a channel through which a polymer is to be translocated. For example, U.S. Pat. Nos. 5,795,782 and 6,015,714 illustrate conductance monitoring methods that may be adapted for use in various aspects of the present invention. For example, current fluctuation events taking place in the range of a few microseconds may be detected and recorded (Hamill et al., 1981, Pfluegers Arch. Eur. J. Physiol., 391: 85-100). In purified planar lipid bilayer systems (such as disclosed in U.S. Pat. Nos. 5,795,782 and 6,015,714; Wonderlin et al., supra), conductance measurements may be facilitated by using bilayers formed over very small diameter apertures (10-50 microns). Some embodiments of such techniques may have the advantage of allowing access to both sides of the bilayer, and may facilitate use of a larger bilayer target for reconstitution with the pore protein. Similarly, U.S. Pat. No. 6,267,872 describes methods and apparatus for producing and using single nanopores to measure ionic current flow through the nanopore.

Methods are available for determining the characteristics and conductance properties of a wide variety of pore molecules (channels), which may be used in various aspects of the invention(U.S. Pat. Nos. 5,795,782 and 6,015,714; Sigworth et al., supra; Heinemann et al., 1988, Biophys. J., 54: 757-64; Wonderlin et al., 1990, Biophys. J., 58: 289-97). For example, in the pipette bilayer technique, an artificial bilayer containing at least one pore protein is attached to the tip of a patch-clamp pipette by applying the pipette to a preformed bilayer reconstituted with the purified pore protein in advance. The very narrow aperture diameter of the patch pipette tip (2 microns) facilitates a reduction in background noise in this technique, and in some applications the limit for detectable current interruptions may be about 10 microseconds (Sigworth et al., supra; Heinemann et al., 1990, Biophys. J., 57: 499-514). In some applications, purified channel proteins may be inserted in a known orientation into preformed lipid bilayers by standard vesicle fusion techniques (Schindler, 1980, FEBS Letters, 122: 77-79), or other means, and high resolution recordings may then be made to determine the characteristics of the channel. In some embodiments, the membrane surface may be oriented away from the pipette, to that it is accessible while recording. This may for example facilitate applications wherein the pore is introduced into the solution within the patch pipette rather than into the bath solution.

A polymer may be advanced through a nanopore channel by attaching a magnetic bead to the polymer (see Anazawa et al.; U.S. Pat. No. 6,136,543; Fry et al. Biotechniques (1992) 13(1):124-31) and by using a magnetic field to push or pull the bead and polymer. For example, to insert a nucleic acid molecule into a pore in some embodiments of the invention, a magnetic bead may be attached to one end of a duplex and biotin attached to the other end. The duplex may then be inserted into the pore so that a steptavidin-bead complex attaches to the biotinylated end of the duplex to retain the duplex in the pore. Alternatively, A polymer may be advanced through a nanopore or channel using electrophoretic current, for example as described in Kasianowicz et al. Proc. Natl. Acad. Sci. USA 93:13770-73; Akeson et al. Biophysical Journal 77:3227-33; Meller et al. Proc. Natl. Acad. Sci. USA 97(3):1079-84; Howorka et al. Proc. Natl. Acad. Sci. USA 98(23):12996-13001. In some embodiments, a chemical potential difference may be established across an interface or bilayer to force polymers through a channel without supplying an external potential difference across the membrane. In such embodiments, the membrane potential may be varied ionically to produce more or less of a differential or “push” (see for example U.S. Pat. Nos. 5,795,782 and 6,015,714).

In some embodiments, the passage of polynucleotides through a channel may be slowed to facilitate sensing individual nucleotide pairs (as described in U.S. Pat. Nos. 5,795,782 and 6,015,714). in various embodiments, approaches to accomplish this may for example include: (a) increasing the viscosity of the medium, (b) establishing the lower limit of applied potential that will move polynucleotides into the channel (c) use of high processivity polymerase in the trans compartment to “pull” DNA through the pore in place of voltage gradients (d) adjusting the rate at which the magnetic bead coupled to the polymer is pulled or pushed. In some embodiments, enzymes may be used to translocate the polymer through the pore or channel.

Although various embodiments of the invention are disclosed herein, many adaptations and modifications may be made within the scope of the invention in accordance with the common general knowledge of those skilled in this art. Such modifications include the substitution of known equivalents for any aspect of the invention in order to achieve the same result in substantially the same way. For example, In alternative embodiments, lipid composition of the bilayer may include a wide variety of non-polar (and polar) components which are compatible with pore or channel protein incorporation. The configuration of recording apparatus (e.g., bilayer across aperture, micropipette patches, intra-vesicular recording) may be selected for such alternative embodiments such that signal detection is in an appropriate range.

### EXAMPLE

Introduction

The following example is illustrative of various aspects of the present invention. As set out in detail below, a 50 base guide strand was synthesized which consisted of a central 10 base probe sequence flanked by two tracts of 20 adenine residues. Target sequences of 10 bases containing up to three mismatches were prepared and hybridized to the guide strand in 1 M KCl. The transport of these constructs through single alpha-hemolysin pores was analysed by measuring the current blockade as a function of time. Complementary ds-DNA takes significantly longer (1100±250 ps) to pass through the pore than a sequence of the same length containing a single mismatch (155±95 μs). Constructs involving 2 and 3 mismatches were indistinguishable from ss-DNA transport. Duplexes containing mismatches unzip more quickly and can be distinguished from those with perfect complimentarity.

Results and Discussion

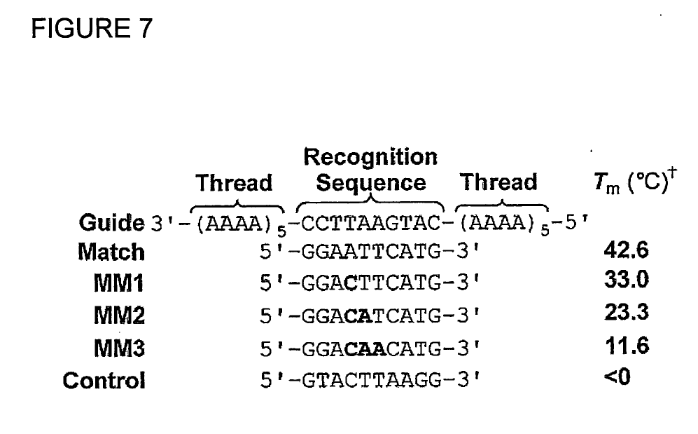

The DNA sequences used are shown in FIG. 7. A strand of DNA, termed the Guide, was synthesised to contain a 10-mer recognition sequence that was flanked by two 20-mers of adenosine, labelled as threads in FIG. 7. The purpose of Guide is to have the thread section lead the probe sequence into the pore cavity for subsequent transport. Oligo(dA) was chosen as the thread sequence because it exhibits the largest blockage current and it also takes the longest to transit the pore, ensuring the largest signal to noise ratio and better time resolution. Four sets of target sequences were synthesized containing 0 (Match), 1 (MM1), 2 (MM2) and 3 (MM3) mismatching base pairs as part of the 10-bp recognition sequence. In addition, a control strand was synthesized which is complimentary to the probe but in the opposite orientation (3′ to 5′ direction). The estimated melting temperatures of the resulting duplexes were calculated with MeltCalc (Schütz, E., Von Ahsen, N., BioTechniques 1999, 27, 1218-28) and are included in FIG. 7. MM3 and the control will not form stable duplexes under these conditions and that the duplex formed with MM2 and the probe will have limited stability at 21° C.

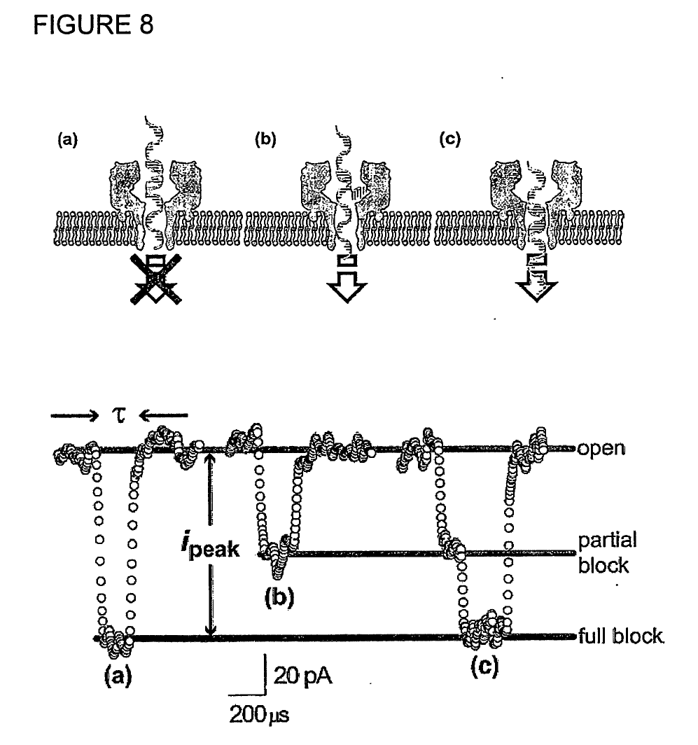

A typical ss-DNA translocation event is shown in FIG. 8a, a typical partial blockage event is shown in FIG. 8b and a rare (˜1 event in every 500 events) partial blockage event followed immediately by a full blockage event is shown in FIG. 8c. ipeak is the difference between the open pore current and the maximum blockage current. Likewise, the duration of the pore blockage, tau, is measured as the time the current takes to return to the open pore state. Typical values for ipeak and tau are 80 pA and 200 μs, respectively, for translocation of a 50-mer of ss-DNA.

The guide and the targets were pre-hybridized before injection in to the bilayer chamber to ensure maximum duplex formation and minimize single-stranded events. A typical experiment involves injecting 10 μL of a 10 μM ds-DNA solution into a 1.5 mL chamber as close to the aperture as possible without rupturing the bilayer. Immediately following the injection of a sample, recording of the translocation events was commenced. Intermittently, the pore became blocked for durations longer than 10 s at which time, a reversal of potential was applied for ˜1 s and typical DNA translocation behaviour returned. This type of permanent blockage is rare (approximately 1 event in 10 minutes) and may be attributed to secondary structures that cannot unfold once positioned in the pore, such as hairpins.

Acquisition of many translocation events (n>1500) allowed for a statistical treatment of the data where each event can be described as belonging to a population. Plotting the ipeak values of one experiment as a histogram allows a statistical description of the pore blockage current. Fitting the distributions to Gaussian curves provides valuable information that describes characteristics belonging to the population and allows for comparisons between populations.

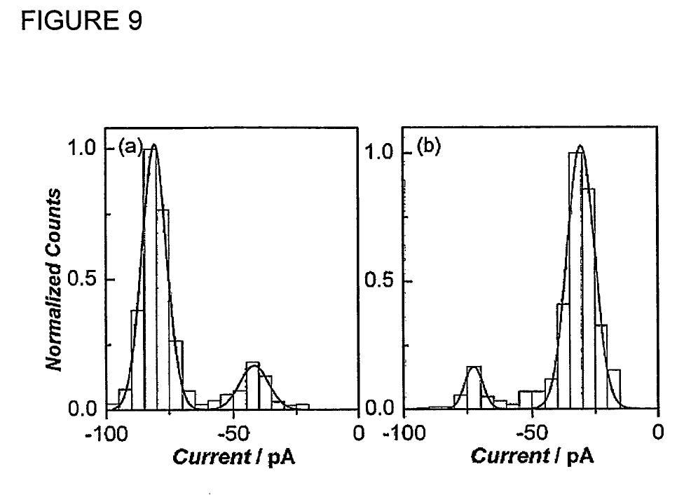

A comparison between ss-DNA (Guide) and ds-DNA (Guide:Match) is made in FIG. 9. In the ss-DNA case, FIG. 9a, there are two distributions with peak centers at −42(1) pA and −81(1) pA, respectively. As described in FIG. 8a, the peak centered at −81 pA represents the DNA that transits the pore and the peak centered at −42 pA represents the DNA that collides with the pore and does not result in a translocation event (FIG. 8b). The areas of the peaks represent the probability that an event will fall into either of these two categories. Clearly, in the ss-DNA case, a collision will most likely (84%) result in the DNA transporting through the pore.

Conversely, in the ds-DNA case, the two peaks are centered at −31(1) pA and −73(3) pA, respectively, and the most probable events (90%) are those collisions that result in no translocation. Additionally, the averaged peak widths at half maximum are 10(2) pA and 11(4) pA for ss- and ds-DNA, respectively, suggesting that the interaction with the pore is-more variable for ds-DNA compared to ss-DNA. It is also worth noting that the absence of multiple peaks for the full blockage events suggests no orientation preference (3′ to 5′ or 3′ to 5′) for transport.

The ipeak value is a volumetric measure of the degree to which the pore is occupied. Since the volume occupied by a duplex is much larger than a single strand, the ipeak value for a duplex may be much larger than for a ss-DNA. Therefore, the similarity in ipeak values for ss- and ds-DNA is evidence that the ds-DNA unzips before it can transit the pore. In accordance with an unzipping model, there should be a difference in the unzipping kinetics for differently matched ds-DNA fragments.

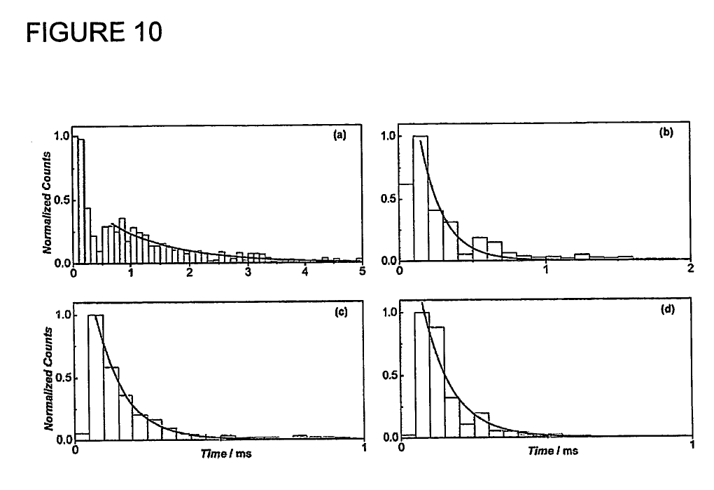

A collection of blockage durations were analysed for each system and the results are shown in FIG. 10. Note that only events that had ipeak values greater than 60 pA were included in the blockage duration histograms. This screening process was used since the increase in the number of partially blocked events in the ds-DNA case would overwhelm the number of translocation events. The translocation events were plotted to produce a profile that could be described by a mono-exponential decay defined by a lifetime value. A mono-exponential fit was used as minimalist approach to describe the population.

The results show that Guide:Match (tau=1100(250) μs, FIG. 10a) takes much longer to transit the pore than the Guide:MM1 (tau=155(25) μs, FIG. 10b), Guide:MM2 (tau=100(10) μs, FIG. 10c), or Guide:MM3 ( tau=100(30) μs, FIG. 10d). In addition, the Guide only and Guide:Control both gave blockage lifetimes of 100(20) μs, whereas the value for the 10-base Match sequence was 42(10) μs (data not shown). In the profile of the blockage duration of the Guide:Match hybrid there are two populations evident; one at short time-scales (100 μs) and one at the much longer time scales, as shown by the fit curve in FIG. 10a. Based on the control experiments, some of these events can be tentatively assigned as unhydribized Guide DNA. The lifetimes for Guide:MM2 and Guide:MM3 are indistinguishable from the Guide only which is consistent with the Tm values (FIG. 7); the presence of 2 or 3 mismatches in a 10 bp DNA duplexes essentially renders it single-stranded. On the other hand, Guide:MM1 has a Tm which is about 10 ° C. above the experimental temperature and the corresponding lifetime is significantly increased compared to the Guide only. The Tm value of the Guide:Match is the highest and gives rise to the longest transit time consistent with the requirement for unzipping before transport.

Experimental Section

Alpha-HL was purchased from Sigma-Aldrich and used without purification. KCl, NaH2PO4, NaH2PO4 and decane were purchased from Aldrich and used as received. DiPhytanoyl-phosphatidyl choline in CHCl3 was purchased from Avanti Polar lipids. DNA was purchased from the Plant Biotechnology Institute (National Research Council, Saskatoon) and used as received. Millipore water (18 M.·cm) was used in all solutions. The CHCl3 lipid solution was dried under vacuum for a minimum of 4 hours and then suspended in decane to a final concentration of 30 mg·mL−1 of lipid. Supporting electrolyte for all bilayer measurements was 1 mM phosphate buffer (pH 8) in 1.0 M KCl.

The alpha-HL solution was made up to a final concentration of 3.28 μg·mL−1 in 100 mM KCl and 1 mM phosphate buffer (pH 8) and stored at 4° C. DNA hybridization was done at 21° C. in 1 M KCl containing 10 mM phosphate buffer (pH 8) for 12 hours.

The bilayer cell and cell holder were purchased from Warner instruments. The perfusion cell has a volume of 1.5 mL and a limiting aperture size of 150 μm. Before bilayer formation can occur the decane/lipid suspension is applied to the aperture and excess lipid is dried under a stream of argon. The cell is filled with 1.5 mL of electrolyte and place in a bath of the same electrolyte. The bilayer cell is encased in solid copper, which rests on a thin insulating support. The entire apparatus is placed within a Faraday cage (Warner Instruments) and rests on an active air floating table (Kinetic Systems). The two compartments of the bilayer cell are termed cis and trans where the trans compartment is defined as being at virtual ground. The bilayer experiments were run under voltage clamp conditions using an Axopatch 200B amplifier (Axon Instruments) connected to a CV 203BU headstage. Currents were low pass Bessel filtered at 10 kHz and were digitized at 250 kHz by DigiData 1322A (Axon Instruments) and recorded by a PC running PClamp 9.0 (Axon Instruments). Analysis of all data was performed by ClampFit 9.0 (Axon Instruments) and Origin 7.0 (OriginLab Corporation).

Bilayers were formed by dipping a fine paint brush into the lipid suspension and painting across the aperture. Bilayer formation was monitored by capacitance measurements automatically performed by PClamp 9.0. Gradual removal of lipid and thinning of the multilayer to a bilayer was done by repeated strokes of the brush until acceptable capacitance values were obtained. A lipid bilayer was deemed stable if it was able to withstand 150 mV at both polarities for a period of 10 minutes each without current “spikes”. 5 μL of the alpha-HL solution was injected adjacent to the aperture in the trans chamber and pore insertion was determined by a defined jump in current values. Once a stable single pore insertion was detected, the DNA solution was added to the trans chamber, proximal to the aperture and a positive potential was applied.

### Conclusion

Numeric ranges recited herein are inclusive of the numbers defining the range. In the specification, the word “comprising” is used as an open-ended term, substantially equivalent to the phrase “including, but not limited to”, and the word “comprises” has a corresponding meaning. Citation of references herein shall not be construed as an admission that such references are prior art to the present invention. All publications, including but not limited to patents and patent applications, cited in this specification are incorporated herein by reference as if each individual publication were specifically and individually indicated to be incorporated by reference herein and as though fully set forth herein. The invention includes all embodiments and variations substantially as hereinbefore described and with reference to the examples and drawings.

### REFERENCES

All of the following documents, and other references recited herein, are hereby incorporated by reference:
Aich and Lee (1999) International Patent Publication WO 99/31115.
Aich, P., Labiuk, S. L., Tarl L. W., Delbaere, L. J. T., Roesler, W. J., Faulk, K. J., Steer, R. P., and Lee, J. S. Journal of Molecular Biology 294(2), 477-485 (1999).
Akeson, M., Branton, D., Kasianowicz, J. J., Brandin, E., Deamer, D. W., Biophys. J. 1999, 77, 3227-33.
Braun, E., Eicher, Y., Sivan, U., and Ber-Yoseph, G. Nature 391, 775-778 (1998).
Gelbart, W. M., Bruinsma, R. F., Pinkcus, P. A., and Parsegian, V. A. Physics Today 53, September 2000, 38-44 (2000).
Heller and Tu, U.S. Pat. No. 6,067,246.
Hopfield, J. J., Onuchic, J. N. and Beratan, D. N., “A Molecular Shift Register”, Science, 241, p. 817 (1988).
Howorka et al. in Nat. Biotech. 19(7):636-639 (2001).
Howorka et al. Proc. Natl. Acad. Sci. USA 98(23):12996-13001;
Kasianowicz et al. Proc. Natl. Acad. Sci. USA 93:13770-73;
Lee, J. S., Latimer, L. J. P., and Reid, R. S. Biochem. Cell Biol. 71, 162-168 (1993).
Lewis, F. D., Wu, T., Zhang, Y., Letsinger, R. L., Greenfield, S. R., and Wasielewski, M. R. Science 277, 673-676 (1997).
Lines, M. E., and Glass, A. M. Principles & Applications of Ferroelectrics & Related Materials (Clarendon Press, Oxford, 1977).
Meller et al. Proc. Natl. Acad. Sci. USA 97(3):1079-84;
Porath, D, Bezryadin, A., de Vries, S., and Dekker, C. Nature 403, 635-638 (2000).
Ratikin A., Aich P., Papadopoulos C., Kobzar Y., Vendeneev A. S., Lee J. S. and Xu J. M. Phys. Rev. Lett. 86(16):3670-3673 (2001).
Robinson et al, “The Design of a Biochip: A Self-Assembling Molecular-Scale Memory Device”, Protein Engineering, 1:295-300 (1987).
Seeman, N. C., and Kallenback, N. R. Ann. Rev. Biophys. Biomol. Struct 23, 53-86 (1994).
Sponer, J., Burda, J. V., Leszczynski, J., and Hobza, P. J. Biomol. Struct. Dyn. 17, 61 (1999).
Taubes, G. Science 275,1420-1421 (1997).
Vercoutere, W., Winters-Hilt, S., Olsen, H., Deamer, D., Haussier, D., Akeson, M., Nat. Biotechnol. 2001,19, 248-52.
Wang J., Rivas G., Jiang M., and Zhang X. Langmuir. 15, 6541-6545 (1999).
U.S. Pat. Nos. 6,267,872; 6,015,714 and 5,795,782

1. A process of recording information in a nucleic acid polymer, comprising:
a) modulating the translocation of first and second nucleic acid strands through a channel between a dissociation medium and a hybridization medium, while modulating an electrostatic potential across the channel to modulate the incorporation of a metal ion in a nucleic acid duplex as the duplex forms in the hybridization medium;
b) wherein the channel separating the hybridization medium and the dissociation medium is dimensioned to allow lineal translocation of the nucleic acid duplex or a metal-containing nucleic acid duplex between the hybridization medium and the dissociation medium;
c) and wherein the first and the second nucleic acid strands comprise a plurality of nitrogen-containing aromatic bases covalently linked by a backbone, the nitrogen-containing aromatic bases of the first nucleic acid strand being capable of being joined by hydrogen bonding in the hybridization medium to the nitrogen-containing aromatic bases of the second nucleic acid strand so that the nitrogen-containing aromatic bases on the first and the second nucleic acid strands form hydrogen-bonded base pairs in stacked arrangement in the nucleic acid duplex, the hydrogen-bonded base pairs being capable of interchelating the metal cation coordinated to a nitrogen atom in one of the aromatic nitrogen-containing aromatic bases to form the metal-containing nucleic acid duplex.

2. The process of claim 1, further comprising the step of reading information from the nucleic acid polymer by detecting the presence or absence of the metal cation in the nucleic acid duplex.

3. The process of claim 2, wherein the presence or absence of the metal cation is detected by measuring the electrical conductance across the channel as the nucleic acid duplex is translocated through the channel between the hybridization medium and the dissociation medium.

4. The process of claim 1, wherein the nucleic acid duplex is coupled to a magnetic bead, and the translocation of the nucleic acid duplex through the channel is mediated by modulating the magnetic field across the channel.

5. The process of claim 1, wherein the channel is formed in a lipid membrane.

6. The process of claim 1, wherein the channel is a pore forming protein.

7. The process of claim 1, wherein the hybridization medium and the dissociation medium are electrically conductive aqueous solutions.

8. The process of claim 1, wherein the first and the second nucleic acid strands are deoxyribonucleic acids and the nitrogen-containing aromatic bases are selected from the group consisting of adenine, thymine, guanine and cytosine.

9. The process of claim 1, wherein the metal cation is selected from the group consisting of Zn²⁺, Co²⁺, and Ni²⁺.

10. The process of claim 1, wherein the metal cations are substituted for imine protons of the nitrogen-containing aromatic bases, and the nitrogen-containing aromatic bases are selected from the group consisting of thymine and guanosine.

11. The process claim 1, wherein at least one of the aromatic nitrogen-containing aromatic bases is thymine, having an N3 nitrogen atom, and the metal cation is coordinated by the N3 nitrogen atom.

12. The process of claim 1, wherein at least one of the aromatic nitrogen-containing aromatic bases is guanine, having an N1 nitrogen atom, and the metal cation is coordinated by the N1 nitrogen atom.

13. A process for detecting a base pair mismatch in a nucleic acid polymer, comprising:
a) detecting the presence or absence of divalent metal cations in base pairs of a nucleic acid duplex by measuring electrical conductance across a channel as a metal-containing nucleic acid duplex is translocated through the channel;
b) wherein the channel separates a first pool and a second pool of a medium, the channel being dimensioned to allow sequential monomer-by-monomer lineal translocation of the metal-containing nucleic acid duplex between the first and second pools of the medium;
c) wherein the nucleic acid duplex comprises a first strand of nucleic acid and a second strand of nucleic acid, the first and the second nucleic acid strands comprising a plurality of nitrogen-containing aromatic bases covalently linked by a backbone, at least some of the nitrogen-containing aromatic bases of the first nucleic acid strand matching the nitrogen-containing aromatic bases of the second nucleic acid strand and the matching base pairs being joined by hydrogen bonding to the nitrogen-containing aromatic bases of the second nucleic acid strand, the matching nitrogen-containing aromatic bases on the first and the second nucleic acid strands forming hydrogen-bonded base pairs in stacked arrangement along the length of the nucleic acid duplex;
d) wherein the matching hydrogen-bonded base pairs of the metal-containing nucleic acid duplex comprise an interchelated divalent metal cation coordinated to a nitrogen atom in one of the aromatic nitrogen-containing aromatic bases, and wherein a mismatched base pair does not interchelate a divalent metal cation.

14. A device for storing information comprising a metal-containing nucleic acid duplex housed in the lumin of a channel formed in a membrane.


SEQUENCE LISTING (6 sequences)

SEQ ID NO: 1 - DNA, 50 bp, Artificial Sequence
  Synthetic DNA strand referred to as Guide Sequence
aaaaaaaaaaaaaaaaaaaacatgaattccaaaaaaaaaaaaaaaaaaaa

SEQ ID NO: 2 - DNA, 10 bp, Artificial Sequence
  Synthetic DNA strand referred to as Match Sequence
ggaattcatg

SEQ ID NO: 3 - DNA, 10 bp, Artificial Sequence
  Synthetic DNA strand referred to as MM1 Sequence
ggacttcatg

SEQ ID NO: 4 - DNA, 10 bp, Artificial Sequence
  Synthetic DNA strand referred to as MM2 Sequence
ggacatcatg

SEQ ID NO: 5 - DNA, 10 bp, Artificial Sequence
  Synthetic DNA strand referred to as MM3 Sequence
ggacaacatg

SEQ ID NO: 6 - DNA, 10 bp, Artificial Sequence
  Synthetic DNA strand referred to as Control Sequence
gtacttaagg